(19) United States
(12) Patent Application Publication
(10) Pub. No.: US 2017/0069653 A1
(43) Pub. Date: Mar. 9, 2017

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventors: Shinya NAITO, Toyota (JP); Mitsutoshi NAKAMURA, Kawasaki (JP)

(73) Assignee: Kabushiki Kaisha Toshiba, Minato-ku (JP)

(21) Appl. No.: 15/009,043

(22) Filed: Jan. 28, 2016

Related U.S. Application Data
(60) Provisional application No. 62/216,186, filed on Sep. 9, 2015.

(51) Int. Cl. H01L 27/115; H01L 23/522

(52) U.S. Cl. CPC H01L 27/11582; H01L 27/1157; H01L 23/5226

(57) ABSTRACT

A semiconductor memory device according to an embodiment, includes a semiconductor substrate, a stacked body provided on the semiconductor substrate, a semiconductor pillar provided inside the stacked body, a charge storage film provided between the semiconductor pillar and an electrode film, a tunneling insulating film provided between the semiconductor pillar and the charge storage film, a blocking oxide provided between the charge storage film and the electrode film and
a semiconductor member. The semiconductor member is provided between the tunneling insulating film and the semiconductor substrate, between the charge storage film and the semiconductor substrate, and between the blocking insulating film and the semiconductor substrate. A lower end of the charge storage film is positioned higher than a lower surface of a lower selection gate electrodes and positioned lower than an upper surface of the lower selection gate electrodes.

### CROSS-REFERENCE TO RELATED APPLICATIONS

This application is based upon and claims the benefit of priority from U.S. Provisional Patent Application 62/216,186, filed on Sep. 9, 2015; the entire contents of which are incorporated herein by reference.

### FIELD

Embodiments relate to a semiconductor memory device and a method for manufacturing the same.

### BACKGROUND

In recent years, a stacked type semiconductor memory device has been proposed in which memory cells are integrated three-dimensionally. In such a stacked type semiconductor memory device, a stacked body in which electrode films and insulating films are stacked alternately is provided on a semiconductor substrate; and semiconductor pillars that pierce the stacked body are provided. Also, memory cells are formed at each intersection between the electrode films and the semiconductor pillars. The lower ends of the semiconductor pillars are connected to the semiconductor substrate.

### BRIEF DESCRIPTION OF THE DRAWINGS

FIG. 1 is a cross-sectional view showing a semiconductor memory device according to a first embodiment;

FIG. 2 is a cross-sectional view showing region A of FIG. 1;

FIG. 3A to FIG. 6B are cross-sectional views showing a method for manufacturing the semiconductor memory device according to the first embodiment;

FIG. 7 is a cross-sectional view showing an operation of the semiconductor memory device according to the first embodiment;

FIG. 8 is a cross-sectional view showing an operation of a semiconductor memory device according to a comparative example;

FIG. 9 is a cross-sectional view showing a semiconductor memory device according to a first modification of the first embodiment;

FIG. 10 is a cross-sectional view showing a method for manufacturing the semiconductor memory device according to the first modification of the first embodiment;

FIG. 11 is a cross-sectional view showing a semiconductor memory device according to a second modification of the first embodiment;

FIG. 12 is a cross-sectional view showing a method for manufacturing the semiconductor memory device according to the second modification of the first embodiment;

FIG. 13 is a cross-sectional view showing a semiconductor memory device according to a third modification of the first embodiment;

FIG. 14 is a cross-sectional view showing a semiconductor memory device according to a fourth modification of the first embodiment;

FIG. 15 is a cross-sectional view showing a semiconductor memory device according to a second embodiment; and

FIG. 16 is a cross-sectional view showing a semiconductor memory device according to a third embodiment.

### DETAILED DESCRIPTION

A semiconductor memory device according to an embodiment, includes a semiconductor substrate, a stacked body provided on the semiconductor substrate and a semiconductor pillar provided inside the stacked body. The stacked body includes a plurality of insulating films and a plurality of electrode films, each of the insulating films and each of the electrode films are stacked alternately. The semiconductor pillar extends in a stacking direction of the insulating films and the electrode films. The semiconductor memory device further includes a charge storage film provided between the semiconductor pillar and one of the electrode films, a tunneling insulating film provided between the semiconductor pillar and the charge storage film, a blocking oxide provided between the charge storage film and the one of the electrode films and a semiconductor member. The semiconductor member is provided between the tunneling insulating film and the semiconductor substrate, between the charge storage film and the semiconductor substrate, and between the blocking insulating film and the semiconductor substrate. Among the plurality of electrode films, one or more electrode films from the bottom is lower selection gate electrodes. A lower end of the charge storage film is positioned higher than a lower surface of one of the lower selection gate electrodes and positioned lower than an upper surface of the one of the lower selection gate electrodes.

Embodiments the invention will now be described with reference to the drawings.

### First Embodiment

First, a first embodiment will be described.

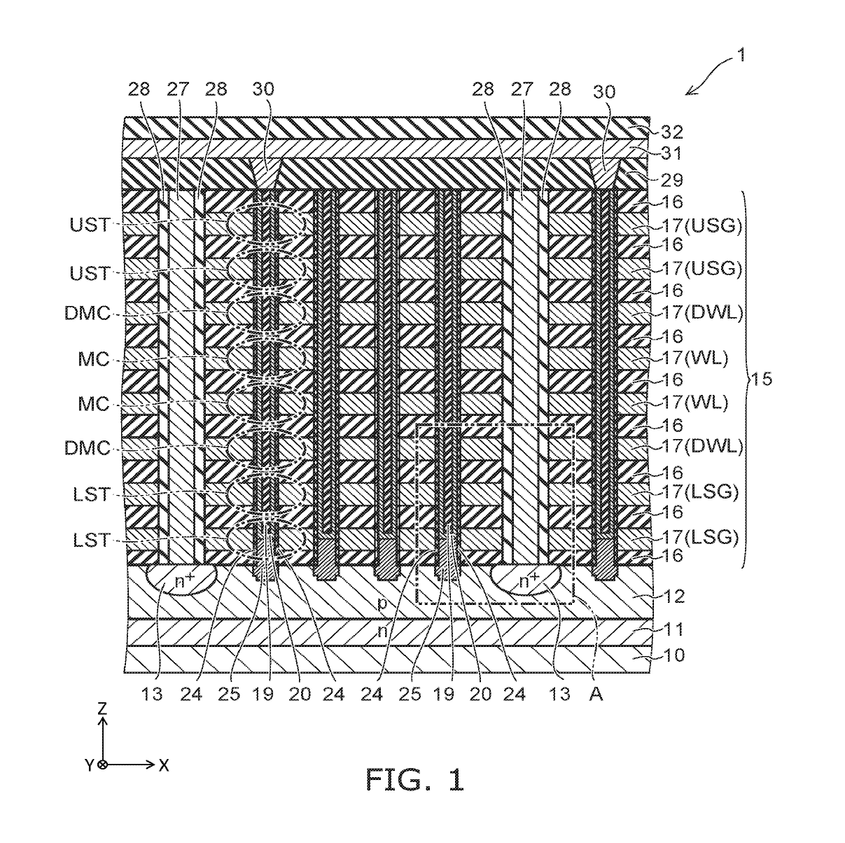

FIG. 1 is a cross-sectional view showing a semiconductor memory device according to the embodiment.

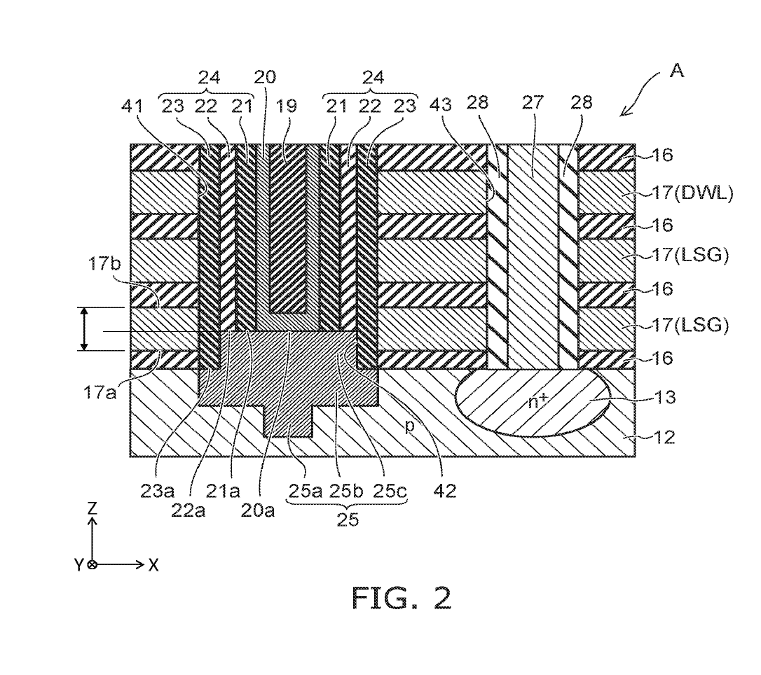

FIG. 2 is a cross-sectional view showing region A of FIG. 1.

As shown in FIG. 1 and FIG. 2, a silicon substrate 10 is provided in the semiconductor memory device 1 according to the embodiment. Hereinbelow, an XYZ orthogonal coordinate system is employed for convenience of description in the specification. Two mutually-orthogonal directions parallel to the upper surface of the silicon substrate 10 are taken as an “X-direction” and a “Y-direction;” and a direction perpendicular to the upper surface of the silicon substrate 10 is taken as a “Z-direction.”

An n-type well 11 that is of an n-type conductivity is provided in the upper layer portion of the silicon substrate 10. A p-type well 12 that is of a p-type conductivity is provided in a portion on the n-type well 11. An n⁺-type diffusion layer 13 that is of the n-type conductivity is provided in a portion on the p-type well 12. The p-type well 12 covers the side surface and lower surface of the n⁺-type diffusion layer 13. Thereby, the n⁺-type diffusion layer 13 is separated from the n-type well 11 by the p-type well 12. The effective impurity concentration of the n⁺-type diffusion layer 13 is higher than the effective impurity concentration of the n-type well 11. The effective impurity concentration refers to the concentration of the impurities contributing to the conductivity of the semiconductor material, and in the case where both an impurity that forms donors and an impurity that forms acceptors are included, refers to the concentration excluding the cancelled portion of the donors and the acceptors. The effective impurity concentration is equal to the carrier concentration. Also, the silicon substrate 10 that includes the n-type well 11, the p-type well 12, and the n⁺-type diffusion layer 13 is formed, as an entirety, of a monocrystal of silicon (Si).

A stacked body 15 is provided on the silicon substrate 10. Insulating films 16 and electrode films 17 are stacked alternately along the Z-direction in the stacked body 15. The numbers of stacks of insulating films 16 and electrode films 17 are not limited to the example shown in FIG. 1 and, for example, may be higher. The insulating film 16 is made of an insulating material such as silicon oxide, etc.; and the electrode film 17 is made of, for example, a metal such as tungsten, etc., or a conductive material such as polysilicon, etc. In the specification, in the Z-direction, the direction from the silicon substrate 10 toward the stacked body 15 is called “up” and the direction from the stacked body 15 toward the silicon substrate 10 is called “down;” but these notations are for convenience and are independent of the direction of gravity.

The electrode films 17 of the first and second levels from the bottom are used as lower selection gate electrodes LSG; the electrode films 17 of the first and second levels from the top are used as upper selection gate electrodes USG; and the other electrode films 17 are used as word lines WL. Among the word lines WL, the word line of the lowermost level and the word line of the uppermost level are used as dummy word lines DWL. The difference between the configurations of the lower selection gate electrodes LSG, the upper selection gate electrodes USG, the word lines WL, and the dummy word lines DWL is described below. The dummy word lines DWL may not be provided. Also, the number of lower selection gate electrodes LSG and the number of upper selection gate electrodes USG are not limited to two and may be one, three, or more.

A silicon pillar 20 that extends in the Z-direction is provided inside the stacked body 15. The silicon pillar 20 is made of, for example, polysilicon; and the configuration of the silicon pillar 20 is a circular tube in which the lower end is plugged. A core member 19 that is made of, for example, silicon oxide is provided inside the silicon pillar 20.

A tunneling insulating film 21 is provided on the side surface of the silicon pillar 20. Although the tunneling insulating film 21 normally is insulative, the tunneling insulating film 21 is a film in which a tunneling current flows when a prescribed voltage within the range of the drive voltage of the semiconductor memory device 1 is applied and is, for example, a single-layer silicon oxide film or an ONO film in which a silicon oxide layer, a silicon nitride layer, and a silicon oxide layer are stacked.

A charge storage film 22 is provided on the tunneling insulating film 21. The charge storage film 22 is a film that can store charge, is formed of, for example, a material having trap sites of electrons, and is formed of, for example, silicon nitride (Si₃N₄).

A blocking oxide 23 is provided on the charge storage film 22. The blocking insulating film 23 is a film in which a current substantially does not flow even when a voltage within the range of the drive voltage of the semiconductor memory device 1 is applied. The blocking insulating film 23 is, for example, a single-layer silicon oxide film. The blocking insulating film 23 may be, for example, a stacked film in which a metal oxide layer such as an aluminum oxide layer, a hafnium oxide layer, etc., is interposed between two silicon oxide layers.

A memory film 24 that is capable of storing data includes the tunneling insulating film 21, the charge storage film 22, and the blocking insulating film 23. Accordingly, the memory film 24 is disposed between the silicon pillar 20 and the electrode film 17. Among the films included in the memory film 24, the charge storage film 22 is the film that has the highest stored charge amount per unit surface area. Also, among the films included in the memory film 24, one or more films of the tunneling insulating film 21 is disposed between the charge storage film 22 and the silicon pillar 20. Further, among the films included in the memory film 24, one or more films of the blocking insulating film 23 is disposed between the charge storage film 22 and the electrode film 17.

A memory cell transistor MC is configured, with the memory film 24 interposed, at each intersection between the silicon pillars 20 and the word lines WL. Thereby, the memory cell transistors MC are arranged in a three-dimensional matrix configuration. The memory cell transistors MC can store the data by storing charge in the memory film 24. Also, dummy memory cell transistors DMC that can store data but are not actually used are configured at the intersections between the silicon pillars 20 and the dummy word lines DWL. Further, lower selection transistors LST are configured at the intersections between the lower selection gate electrodes LSG and the silicon pillars 20; and upper selection transistors UST are configured at the intersections between the upper selection gate electrodes USG and the silicon pillars 20. The lower selection transistors LST and the upper selection transistors UST are transistors that control whether each of the silicon pillars 20 is in a conducting state or a non-conducting state.

Also, a silicon member 25 is provided between the silicon pillar 20 and the p-type well 12 of the silicon substrate 10 and between the p-type well 12 and the memory film 24. The silicon member 25 is formed as one body of polycrystalline silicon or monocrystalline silicon epitaxially grown on the silicon substrate 10.

The configuration of the silicon member 25 is roughly a configuration in which three circular plates are stacked concentrically. In other words, in the silicon member 25, disc units 25a to 25c are stacked in this order from the bottom toward the top. The central axis of the silicon member 25 extends in the Z-direction. Among the disc units 25a to 25c, the disc unit 25a of the lower level has the smallest diameter and is disposed in the region directly under the core member 19. The disc unit 25b of the middle level has the largest diameter and is disposed in the region directly under the core member 19, the silicon pillar 20, and the memory film 24. The disc unit 25c of the upper level is disposed in the region directly under the core member 19, the silicon pillar 20, the tunneling insulating film 21, and the charge storage film 22. Also, the disc units 25a and 25b are disposed inside the silicon substrate 10. In other words, the disc units 25a and 25b are disposed lower than the upper surface of the silicon substrate 10. On the other hand, the disc unit 25c is disposed inside the stacked body 15. In other words, the disc unit 25c is disposed higher than the upper surface of the silicon substrate 10.

A lower end 20a of the silicon pillar 20, a lower end 21a of the tunneling insulating film 21, and a lower end 22a of the charge storage film 22 contact the upper surface of the disc unit 25c of the silicon member 25. The inner side surface of the lower portion of the blocking insulating film 23 contacts the side surface of the disc unit 25c; the outer side surface of the lower portion of the blocking insulating film 23 contacts the insulating film 16 of the lowermost level and the electrode film 17 of the lowermost level; and a lower end 23a of the lower portion of the blocking insulating film 23 contacts the upper surface of the disc unit 25b. The side surface and lower surface of the disc unit 25b and the side surface and lower surface of the disc unit 25a contact the p-type well 12. Thereby, the silicon pillar 20 is connected to the p-type well 12 via the silicon member 25. Also, the silicon member 25 is insulated from the electrode film 17 of the lowermost level by the blocking insulating film 23.

Also, the lower end 22a of the charge storage film 22 and the lower ends of the films on the inner side of the charge storage film 22, i.e., the lower end 21a of the tunneling insulating film 21 and the lower end 20a of the silicon pillar 20, are positioned higher than a lower surface 17a of the electrode film 17 of the lowermost level, i.e., the lower selection gate electrode LSG of the lower level, and are positioned lower than an upper surface 17b of the electrode film 17 of the lowermost level. In the embodiment, the positions in the Z-direction of the lower end 22a of the charge storage film 22, the lower end 21a of the tunneling insulating film 21, and the lower end 20a of the silicon pillar 20 are substantially the same. Accordingly, in the Z-direction, the upper surface of the disc unit 25c also is positioned between the lower surface 17a and the upper surface 17b of the electrode film 17 of the lowermost level. On the other hand, the lower end 23a of the blocking insulating film 23 is positioned lower than the lower surface 17a of the electrode film 17 of the lowermost level. The lower end 21a of the tunneling insulating film 21 may be positioned higher than the lower end 22a of the charge storage film 22; and the lower end 20a of the silicon pillar 20 may be positioned higher than the lower end 21a of the tunneling insulating film 21.

A source electrode 27 that has a plate configuration is provided inside the stacked body 15. The source electrode 27 pierces the stacked body 15 in the Z-direction and extends in the Y-direction. The lower end of the source electrode 27 is connected to the n⁺-type diffusion layer 13 of the silicon substrate 10. An insulating plate 28 that is made of, for example, silicon oxide is provided on the two side surfaces of the source electrode 27. As shown in FIG. 1, the electrode films 17 are divided by two mutually-adjacent source electrodes 27. However, the multiple word lines WL and the dummy word lines DWL that are divided by the source electrodes 27 are connected to each other at one end portion in the Y-direction. In other words, when viewed from the Z-direction, the configurations of the word lines WL and the dummy word lines DWL are comb-shaped configurations. On the other hand, the multiple lower selection gate electrodes LSG and the upper selection gate electrodes USG that are divided by the source electrodes 27 are not connected to each other and can have potentials applied independently. In other words, when viewed from the Z-direction, the lower selection gate electrodes LSG and the upper selection gate electrodes USG have multiple line configurations.

Also, an insulating film 29 is provided on the stacked body 15; and plugs 30 are provided inside the insulating film 29. Bit lines 31 that extend in the X-direction are provided on the insulating film 29. The bit lines 31 are connected to the upper ends of the silicon pillars 20 via the plugs 30. An insulating film 32 is provided on the bit lines 31 to cover the bit lines 31.

Thus, the silicon pillars 20 are connected between the silicon substrate 10 and the bit lines 31. Also, the multiple memory cell transistors MC are connected in series along each of the silicon pillars 20; and the lower selection transistors LST and the upper selection transistors UST are connected at the two ends of the multiple memory cell transistors MC. Thereby, a NAND string is formed in which two upper selection transistors UST, one dummy memory cell transistor DMC, multiple memory cell transistors MC, one dummy memory cell transistor DMC, and two lower selection transistors LST are connected in series between the bit line 31 and the silicon substrate 10.

A method for manufacturing the semiconductor memory device according to the embodiment will now be described.

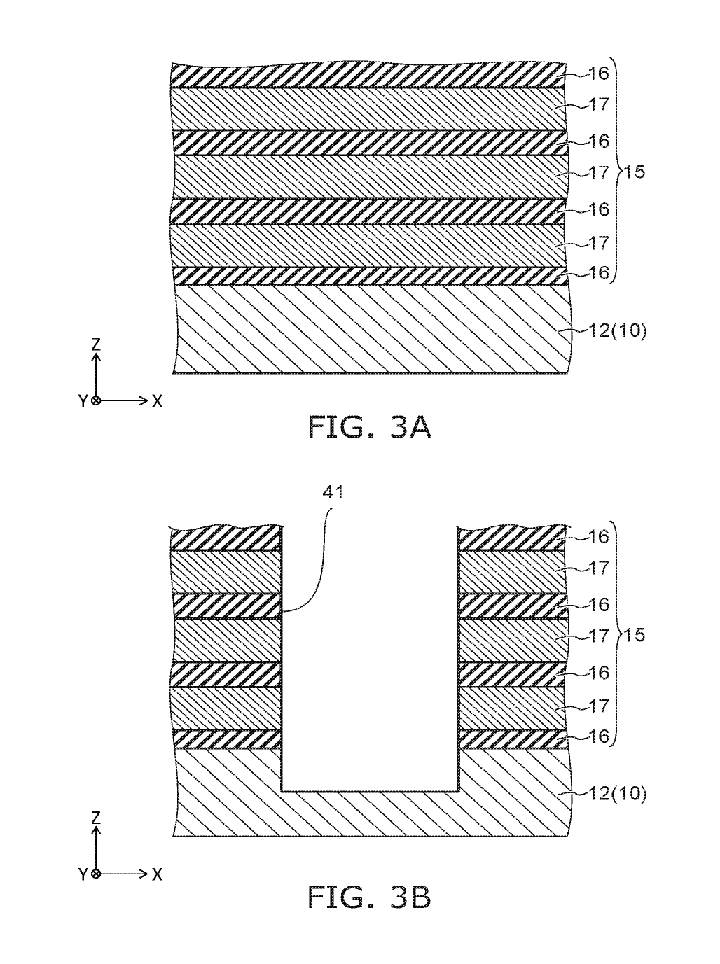

FIG. 3A to FIG. 6B are cross-sectional views showing the method for manufacturing the semiconductor memory device according to the embodiment.

First, the silicon substrate 10 is prepared as shown in FIG. 1. The silicon substrate 10 is a portion of a silicon wafer. Then, the n-type well 11 is formed in the upper portion of the silicon substrate 10 by ion implantation of an impurity that forms donors; and the p-type well 12 is formed in the upper portion of the n-type well 11 by ion implantation of an impurity that forms acceptors.

Then, as shown in FIG. 3A, the stacked body 15 is made on the silicon substrate 10 by alternately stacking the insulating films 16 and the electrode films 17. Only the upper portion of the silicon substrate 10 and the lower portion of the stacked body 15 are shown in FIG. 3A to FIG. 6B.

Then, as shown in FIG. 3B, a memory hole 41 that extends in the Z-direction is made in the stacked body 15 and the upper portion of the p-type well 12 by performing anisotropic etching such as, for example, RIE (Reactive Ion Etching), etc. The memory hole 41 pierces the stacked body 15 and penetrates the upper portion of the p-type well 12 but does not reach the n-type well 11.

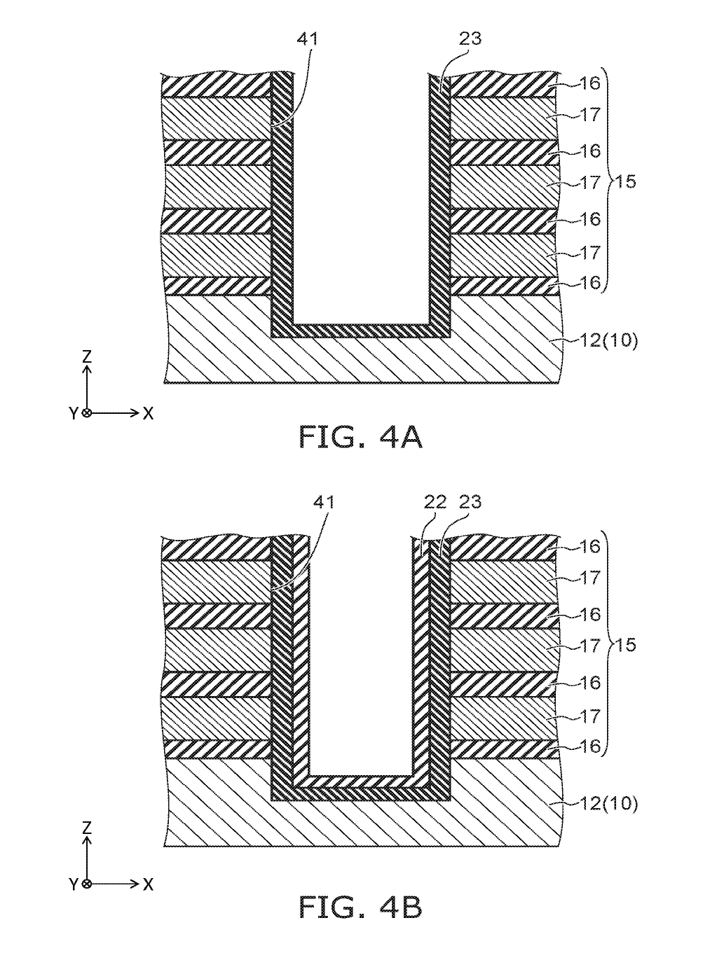

Then, as shown in FIG. 4A, the blocking insulating film 23 is formed on the inner surface of the memory hole 41. For example, the blocking insulating film 23 is formed by depositing silicon oxide.

Then, as shown in FIG. 4B, the charge storage film 22 is formed on the surface of the blocking insulating film 23. For example, the charge storage film 22 is formed by depositing silicon nitride.

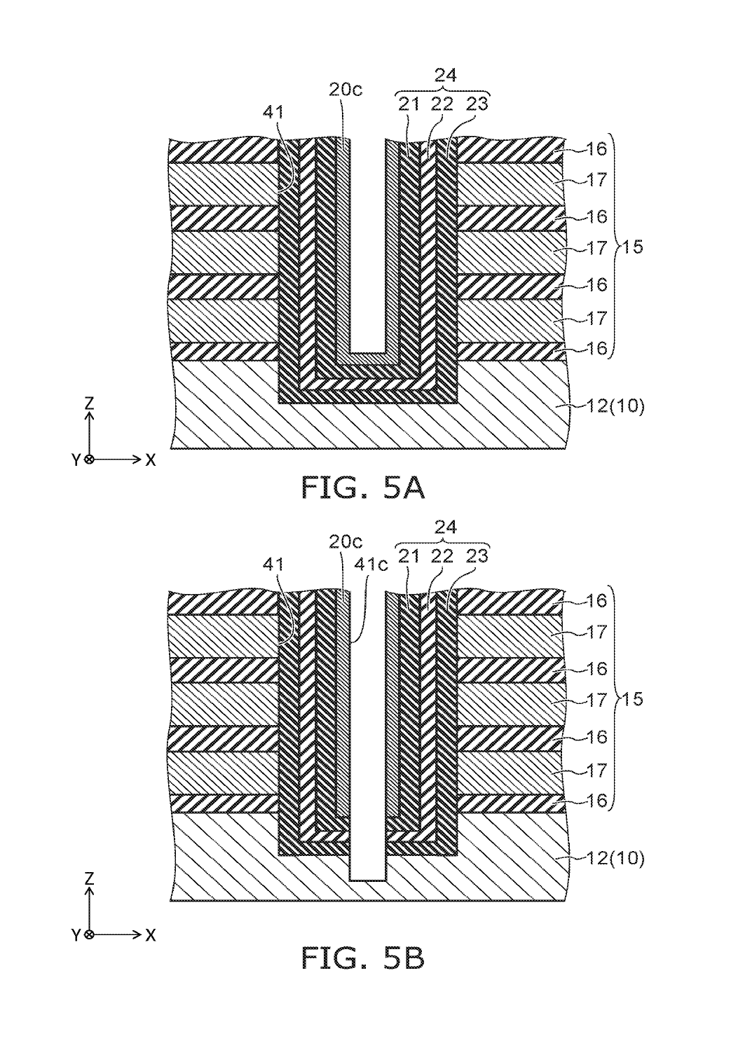

Then, as shown in FIG. 5A, the tunneling insulating film 21 is formed on the surface of the charge storage film 22. For example, the tunneling insulating film 21 is formed by depositing silicon oxide. The memory film 24 includes the blocking insulating film 23, the charge storage film 22, and the tunneling insulating film 21. Then, a cover silicon layer 20c is formed on the surface of the tunneling insulating film 21 by depositing amorphous silicon.

Then, as shown in FIG. 5B, the portions of the cover silicon layer 20c, the tunneling insulating film 21, the charge storage film 22, and the blocking insulating film 23 that are deposited on the bottom surface of the memory hole 41 are removed by performing anisotropic etching such as RIE, etc. Thereby, a central portion 41c of the memory hole 41 positioned in the interior of the cover silicon layer 20c is caused to extend downward, is caused to reach the p-type well 12 of the silicon substrate 10, and is caused, by further over-etching, to penetrate the p-type well 12.

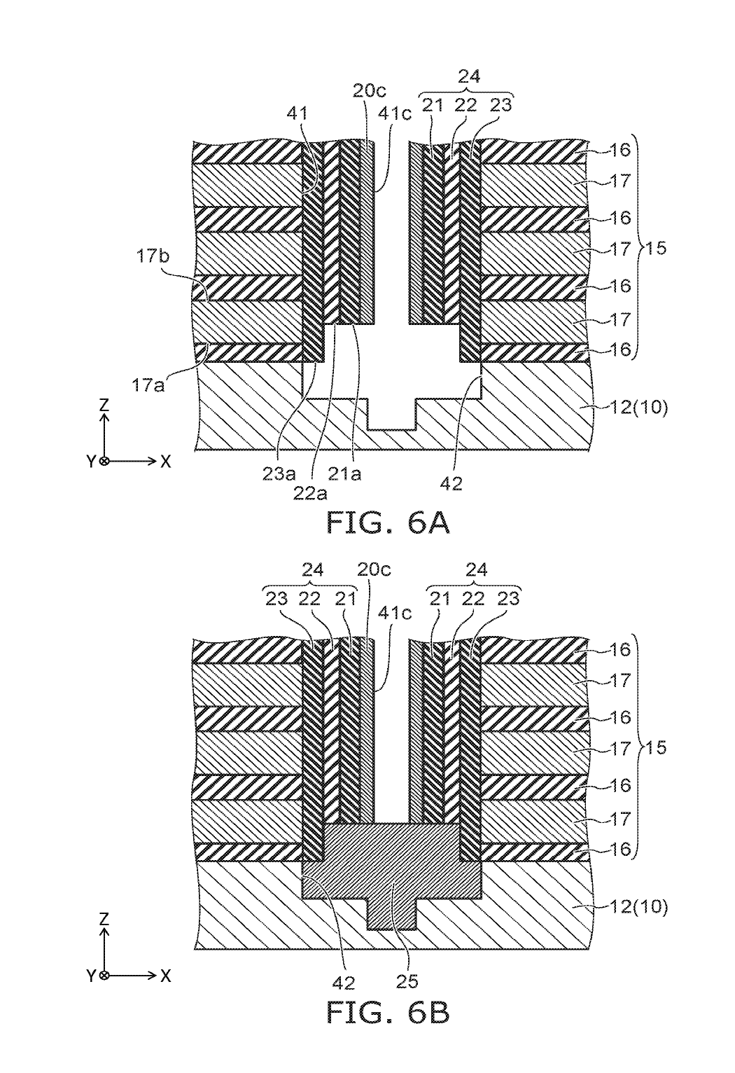

Then, as shown in FIG. 6A, isotropic etching is performed via the central portion 41c of the memory hole 41. At this time, the cover silicon layer 20c that is made of amorphous silicon, the tunneling insulating film 21 that is made of silicon oxide, and the charge storage film 22 that is made of silicon nitride at the lower portion of the memory hole 41 are removed by using, at different timing, an etchant that selectively etches silicon oxide, an etchant that selectively etches silicon nitride, and an etchant that selectively etches silicon so that the lower end of the cover silicon layer 20c, the lower end 21a of the tunneling insulating film 21, and the lower end 22a of the charge storage film 22 are positioned higher than the lower surface 17a of the electrode film 17 of the lowermost level and lower than the upper surface 17b of the electrode film 17 of the lowermost level. On the other hand, the lower portion of the blocking insulating film 23 also is removed so that the lower end 23a of the lower portion of the blocking insulating film 23 is positioned lower than the lower surface 17a of the electrode film 17 of the lowermost level. As a result, an air gap 42 in which the memory film 24 and the cover silicon layer 20c are removed is made in the lower portion of the memory hole 41.

Then, as shown in FIG. 6B, the silicon member 25 is formed inside the air gap 42 by performing epitaxial growth of silicon using the exposed surface of the p-type well 12 as a starting point or by depositing polysilicon by CVD (Chemical Vapor Deposition).

Then, as shown in FIG. 2, the silicon pillar 20 is formed on the inner surface of the memory hole 41 by depositing silicon. At this time, the cover silicon layer 20c (referring to FIG. 6B) becomes a portion of the silicon pillar 20. Then, the interior of the memory hole 41 is filled with the core member 19 by depositing silicon oxide.

Then, a trench 43 that extends in the Y-direction is made in a region of the stacked body 15 where the memory hole 41 is not made by performing anisotropic etching such as, for example, RIE, etc. The trench 43 pierces the stacked body 15 in the Z-direction. Then, the n⁺-type diffusion layer 13 is formed, via the trench 43, in the region of the upper portion of the p-type well 12 directly under the trench 43 by ion implantation of an impurity that forms donors. Then, the insulating plate 28 is formed on the inner surface of the trench 43 by depositing, for example, silicon oxide. Then, the portion of the insulating plate 28 that is disposed on the bottom surface of the trench 43 is removed; and the source electrode 27 is formed inside the trench 43 by depositing a conductive material such as tungsten, etc. The source electrode 27 contacts the n⁺-type diffusion layer 13 and is insulated from the electrode films 17 by the insulating plate 28.

Then, as shown in FIG. 1, the insulating film 29 is formed on the stacked body 15. Then, the plugs 30 that pierce the insulating film 29 are formed so that the lower ends of the plugs 30 are connected to the silicon pillars 20. Then, the bit lines 31 that extend in the X-direction are formed on the insulating film 29 to be connected to the upper ends of the plugs 30. Then, the insulating film 32 is formed on the insulating film 29 to cover the bit lines 31. Then, upper interconnects (not shown) are formed; and dicing of the silicon wafer is performed. Thus, the semiconductor memory device 1 according to the embodiment is manufactured.

Operations and effects of the embodiment will now be described.

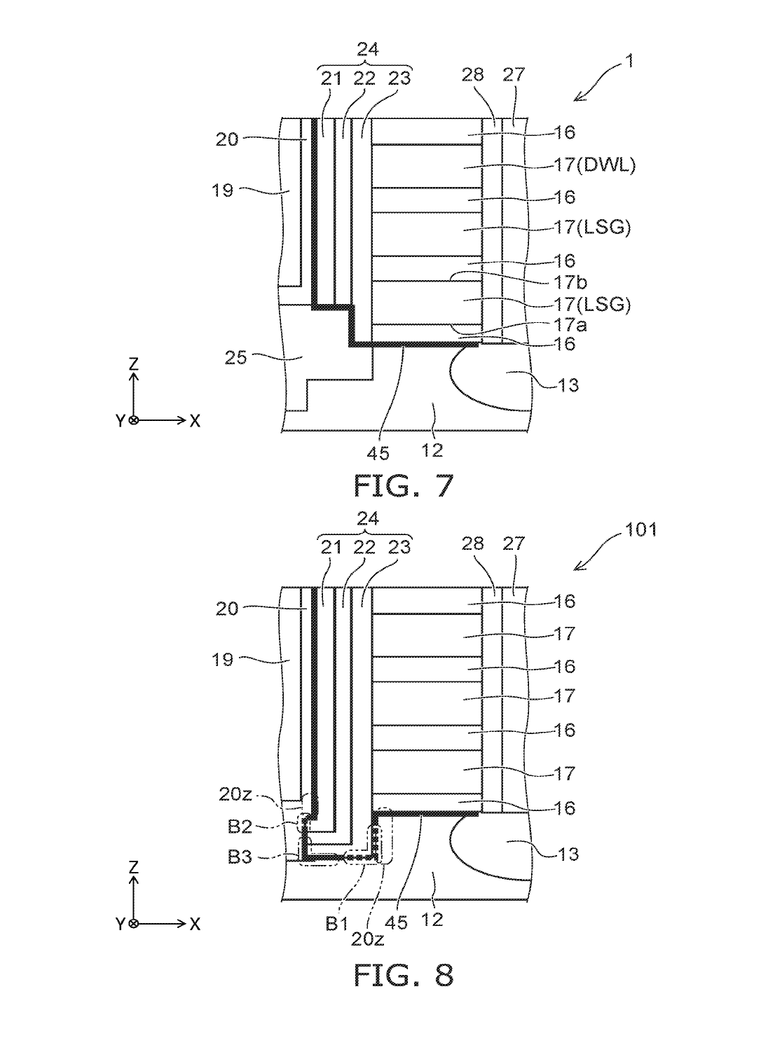

FIG. 7 is a cross-sectional view showing an operation of the semiconductor memory device according to the embodiment.

FIG. 8 is a cross-sectional view showing an operation of a semiconductor memory device according to a comparative example.

In the semiconductor memory device 1 according to the embodiment as shown in FIG. 7, the configuration of the lower end of the memory film 24 is a stairstep configuration that becomes higher toward the inside; and the position of the lower end 22a of the charge storage film 22 in the Z-direction is positioned between the lower surface 17a and the upper surface 17b of the electrode film 17 of the lowermost level, i.e., the lower selection gate electrode LSG of the lowermost level.

Therefore, a conductive member is not interposed between the electrode films 17 and the regions where an inversion layer 45 is to be formed, i.e., the region of the p-type well 12 that contacts the insulating film 16, the region of the silicon member 25 that contacts the memory film 24, and the region of the silicon pillar 20 that contacts the memory film 24. Also, when viewed from the electrode films 17, the regions where the inversion layer 45 is to be formed are at substantially equal distances. Therefore, the inversion layer 45 is formed reliably; and the current path from the source electrode 27 to the silicon pillar 20 is ensured. As a result, the ON current is large. When the ON current is large, the determination in the read-out operation of whether the memory cell transistor MC to be read is in the ON state or the OFF state is easy. Therefore, more memory cell transistors MC can be connected by one NAND string; and higher integration of the semiconductor memory device 1 at a lower cost can be realized.

On the other hand, in the semiconductor memory device 101 according to the comparative example as shown in FIG. 8, the lower end of the memory film 24 extends below the stacked body 15, penetrates the p-type well 12, and bends toward the interior of the memory hole 41. Also, the silicon pillar 20 contacts the p-type well 12; and the silicon member 25 (referring to FIG. 7) is not provided.

Therefore, a portion 12z of the p-type well 12 is interposed between the electrode film 17 of the lowermost level and a region B1 of the p-type well 12 that contacts the memory film 24. Also, a portion 20z of the silicon pillar 20 is interposed between the electrode film 17 of the lowermost level and a region B2 of the silicon pillar 20 that contacts the corner on the upper side of the bent portion of the memory film 24. Accordingly, a conductive portion is interposed between the region B1 and the electrode film 17 of the lowermost level and between the region B2 and the electrode film 17 of the lowermost level; an electromagnetic shielding state occurs; and the electric field generated by the electrode film 17 of the lowermost level does not reach the region B1 and the region B2 easily. In other words, the lines of electric force that are generated from the electrode film 17 of the lowermost level are undesirably terminated before reaching the regions B1 and B2 by the portion 12z and the portion 20z disposed in front of the regions B1 and B2.

Also, as expected, a region B3 of the p-type well 12 and the silicon pillar 20 contacting the corner on the lower side of the bent portion of the memory film 24 is not easily reached by the electric field because the region B3 is distal to the electrode film 17 of the lowermost level.

As a result, it is difficult to form the inversion layer 45 in the regions B1 to B3; and the current path from the source electrode 27 to the silicon pillar 20 is not ensured sufficiently. Accordingly, the ON current is small. When the ON current is small, it is difficult to determine in the read-out operation whether the memory cell transistor MC to be read is in the ON state or in the OFF state.

Thus, according to the embodiment, a semiconductor memory device having a large ON current and a method for manufacturing the semiconductor memory device can be realized.

### First Modification of First Embodiment

A first modification of the first embodiment will now be described.

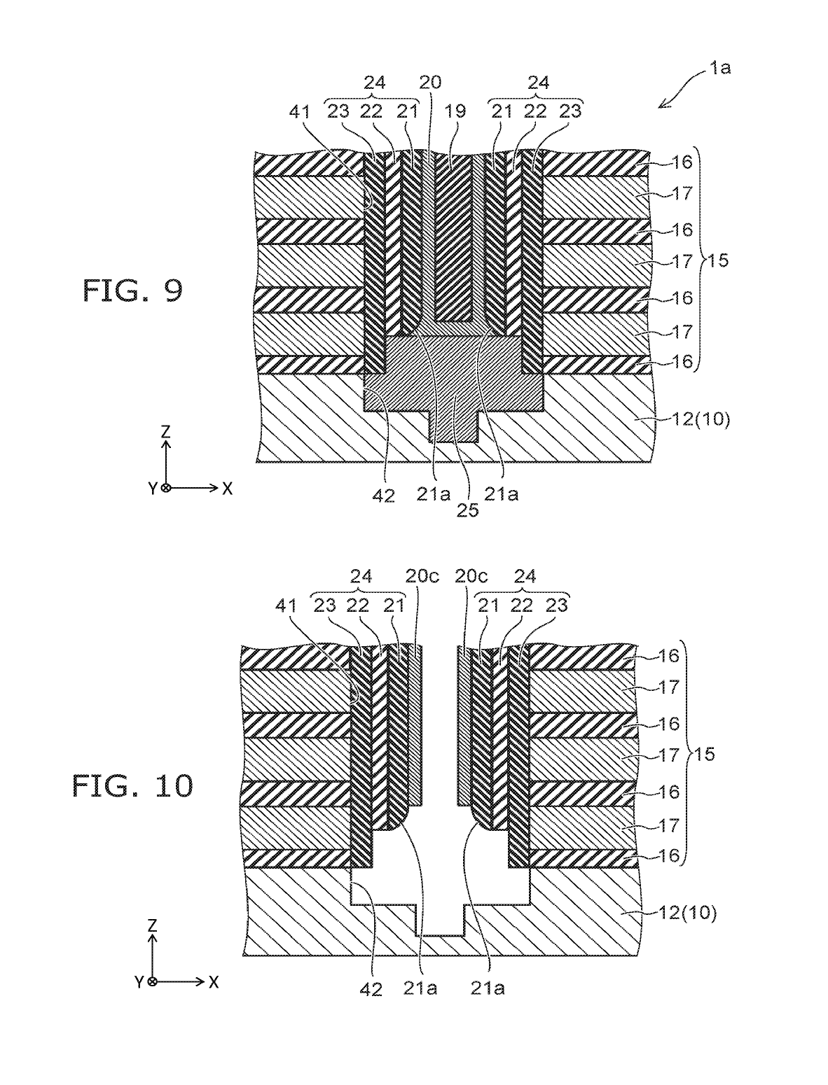

FIG. 9 is a cross-sectional view showing a semiconductor memory device according to the modification.

In the semiconductor memory device 1a according to the modification as shown in FIG. 9, the lower end 21a of the tunneling insulating film 21 becomes higher approaching the silicon pillar 20; and the lower end surface of the lower end 21a is rounded to be convex.

FIG. 10 is a cross-sectional view showing a method for manufacturing the semiconductor memory device according to the modification.

In the modification as shown in FIG. 10, the etching conditions are selected so that the lower end 21a of the tunneling insulating film 21 is rounded when performing the isotropic etching of the memory film 24.

According to the modification, the concentration of the electric field at the corner of the memory film 24 can be relaxed by rounding the lower end 21a of the tunneling insulating film 21. Otherwise, the configuration, the manufacturing method, the operations, and the effects of the modification are similar to those of the first embodiment described above.

### Second Modification of First Embodiment

A second modification of the first embodiment will now be described.

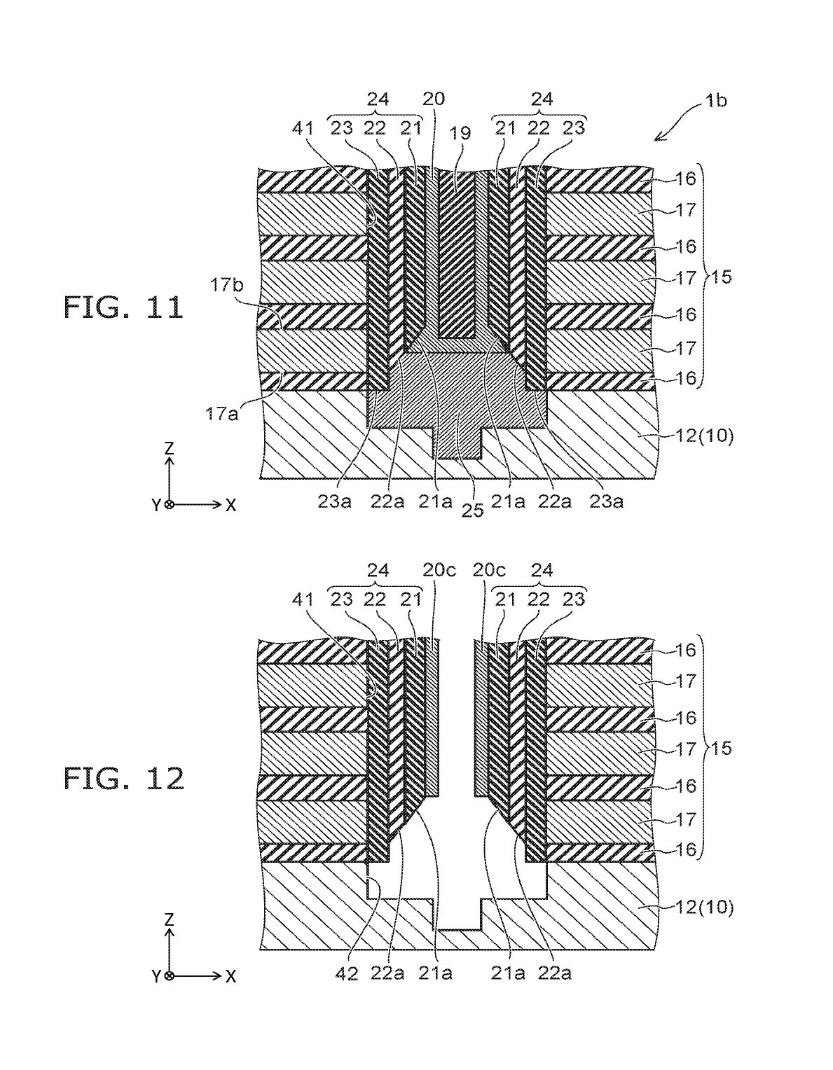

FIG. 11 is a cross-sectional view showing a semiconductor memory device according to the modification.

In the semiconductor memory device 1b according to the modification as shown in FIG. 11, the lower end 22a of the charge storage film 22 and the lower end 21a of the tunneling insulating film 21 are slanted to become higher approaching the silicon pillar 20. Also, the lower end 22a and the lower end 21a are included in a substantially continuous plane. In such a case as well, the lower end 22a of the charge storage film 22 is positioned higher than the lower surface 17a of the electrode film 17 of the lowermost level and lower than the upper surface 17b of the electrode film 17 of the lowermost level. Also, the lower end 22a of the charge storage film 22 contacts the silicon member 25; and the lower end 21a of the tunneling insulating film 21 contacts the silicon pillar 20.

FIG. 12 is a cross-sectional view showing a method for manufacturing the semiconductor memory device according to the modification.

In the modification as shown in FIG. 12, the etching conditions are selected so that the lower end 22a of the charge storage film 22 and the lower end 21a of the tunneling insulating film 21 are slanted when performing the isotropic etching of the memory film 24.

According to the modification, the concentration of the electric field at the corner of the memory film 24 can be relaxed by causing the lower end 22a of the charge storage film 22 and the lower end 21a of the tunneling insulating film 21 to be slanted to become higher approaching the silicon pillar 20. Otherwise, the configuration, the manufacturing method, the operations, and the effects of the modification are similar to those of the first embodiment described above.

### Third Modification of First Embodiment

A third modification of the first embodiment will now be described.

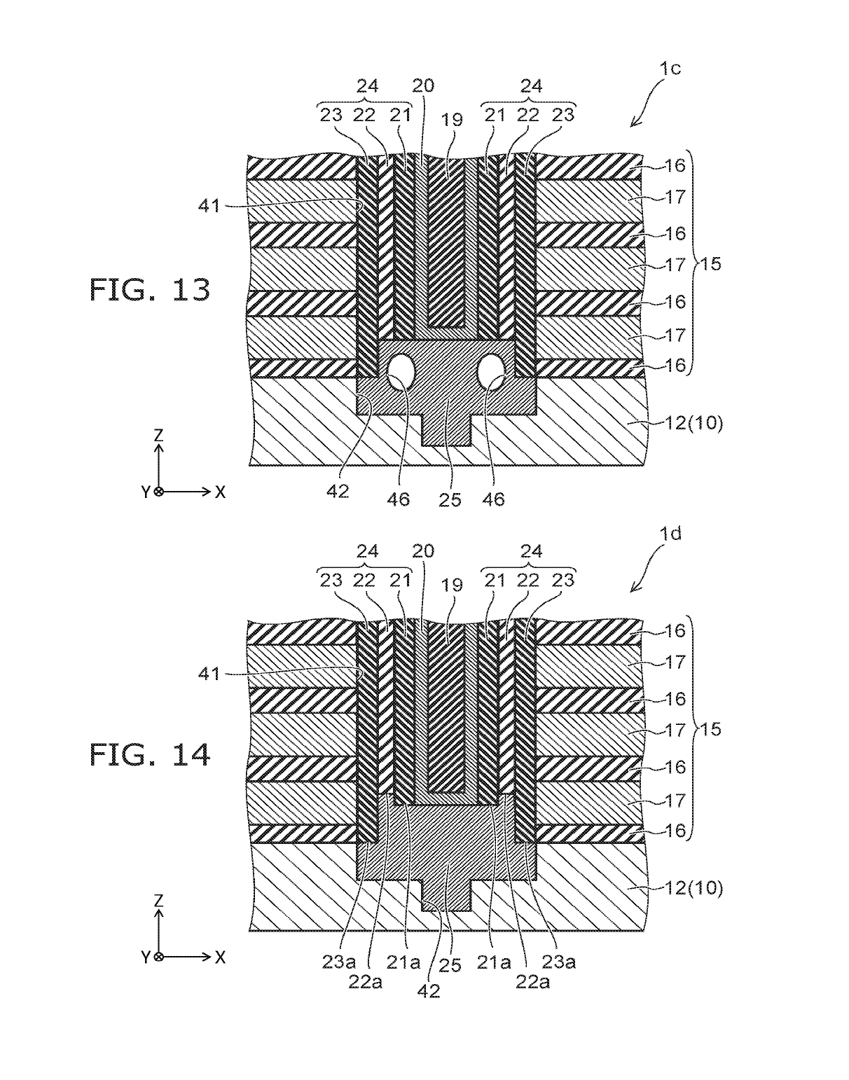

FIG. 13 is a cross-sectional view showing a semiconductor memory device according to the modification.

In the semiconductor memory device 1c according to the modification as shown in FIG. 13, a void 46 is made in the region of the silicon member 25 directly under the memory film 24 and in the vicinity of the region. The void 46 may be one void having an annular configuration or multiple voids communicating with each other along a circle.

Such a void 46 can be made by depositing polysilicon using conditions such that the coverage is low when depositing the polysilicon in the process shown in FIG. 6B.

According to the modification, by making the void 46 inside the silicon member 25, the portion of the silicon member 25 where the inversion layer 45 is not formed (referring to FIG. 7) can be divided somewhat. As a result, the leakage current can be suppressed when the lower selection transistor LST of the lowermost level is switched to the OFF state. Otherwise, the configuration, the manufacturing method, the operations, and the effects of the modification are similar to those of the first embodiment described above.

### Fourth Modification of First Embodiment

A fourth modification of the first embodiment will now be described.

FIG. 14 is a cross-sectional view showing a semiconductor memory device according to the modification.

In the semiconductor memory device 1d according to the modification as shown in FIG. 14, the lower end 22a of the charge storage film 22 is positioned higher than the lower end 23a of the blocking insulating film 23 and the lower end 21a of the tunneling insulating film 21. In other words, the lower end 22a of the charge storage film 22 has a recess at the lower end surface of the memory film 24. However, even in such a case, the lower end 22a of the charge storage film 22 is positioned higher than the lower surface 17a of the electrode film 17 of the lowermost level and lower than the upper surface 17b of the electrode film 17 of the lowermost level. Otherwise, the configuration, the manufacturing method, the operations, and the effects of the modification are similar to those of the first embodiment described above.

### Second Embodiment

A second embodiment will now be described.

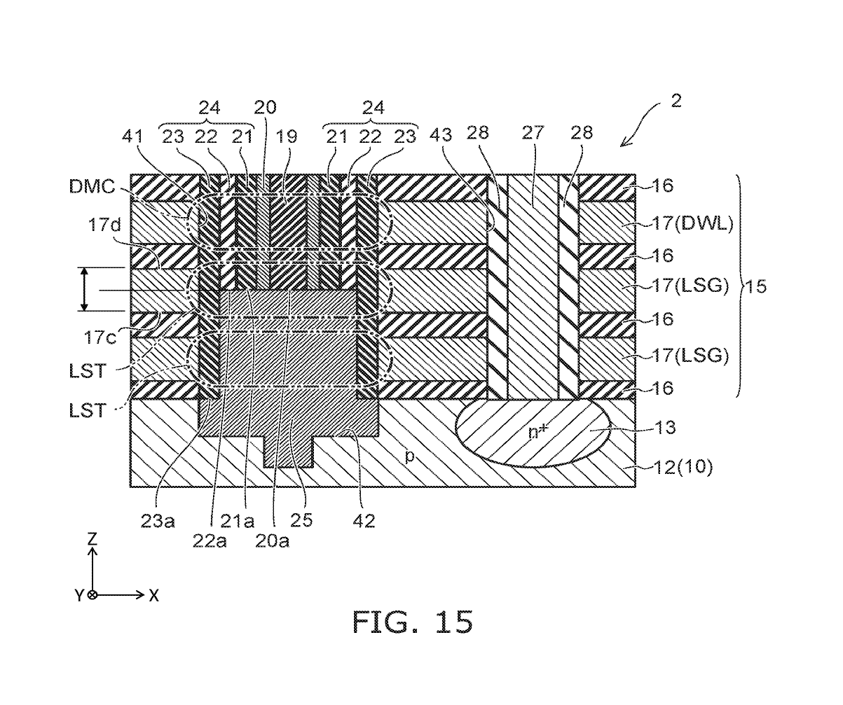

FIG. 15 is a cross-sectional view showing a semiconductor memory device according to the embodiment.

FIG. 15 shows a region corresponding to region A of FIG. 1.

In the semiconductor memory device 2 according to the embodiment as shown in FIG. 15, the lower end 22a of the charge storage film 22, the lower end 21a of the tunneling insulating film 21, and the lower end 20a of the silicon pillar 20 are positioned higher than a lower surface 17c of the electrode film 17 of the second level from the bottom, i.e., the lower selection gate electrode LSG of the second level from the bottom, and lower than an upper surface 17d of the electrode film 17 of the second level from the bottom. Similarly to the first embodiment described above, the blocking insulating film 23 covers the end surface of the electrode film 17 of the lowermost level.

In the embodiment as well, the regions of the p-type well 12 and the silicon member 25 where the inversion layer 45 is formed (referring to FIG. 7) are not electromagnetically shielded by other conductive members; portions that are markedly distal to the electrode films 17 are not formed; and therefore, the inversion layer can be formed stably between the source electrode 27 and the silicon pillar 20.

Otherwise, the configuration, the manufacturing method, the operations, and the effects of the embodiment are similar to those of the first embodiment described above.

### Third Embodiment

A third embodiment will now be described.

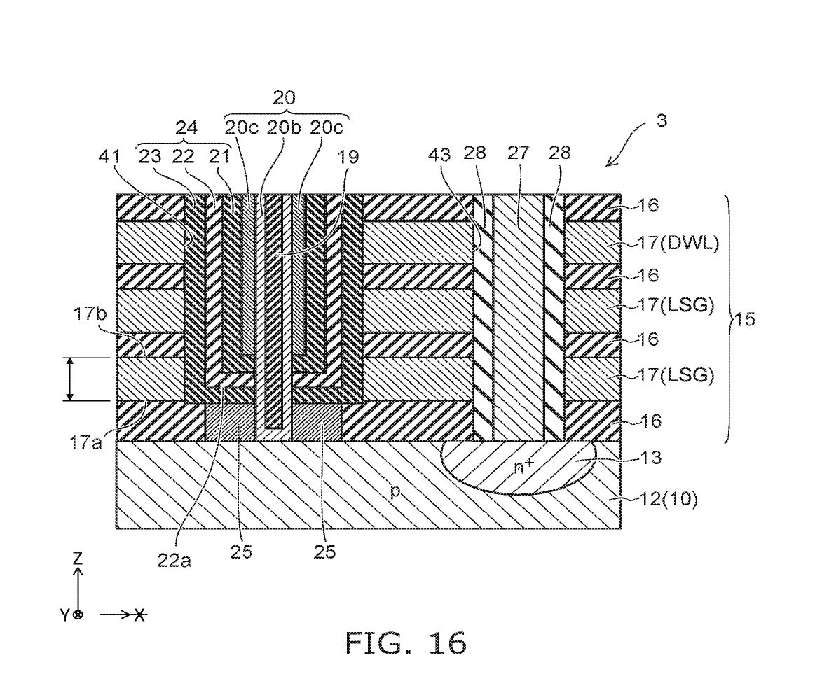

FIG. 16 is a cross-sectional view showing a semiconductor memory device according to the embodiment.

FIG. 16 shows a region corresponding to region A of FIG. 1.

In FIG. 16, the cover silicon layer 20c and a body silicon layer 20b that are included in the silicon pillar 20 are shown separately.

In the semiconductor memory device 3 according to the embodiment as shown in FIG. 16, the silicon substrate 10 is not carved into by the memory hole 41. Also, the body silicon layer 20b of the silicon pillar 20 contacts the p-type well 12 of the silicon substrate 10 without the silicon member 25 being interposed. Therefore, the silicon member 25 is disposed in an annular configuration at the periphery of the silicon pillar 20. Further, the lower portion of the memory film 24 is bent toward the silicon pillar 20. In such a case as well, the lower end 22a of the charge storage film 22, i.e., the lower surface of the portion bent toward the silicon pillar 20, is positioned higher than the lower surface 17a of the electrode film 17 of the lowermost level and lower than the upper surface 17b of the electrode film 17 of the lowermost level. Also, the lower end 23a of the blocking insulating film 23, i.e., the lower surface of the portion bent toward the silicon pillar 20, is positioned lower than the lower surface 17a of the electrode film 17 of the lowermost level.

In the embodiment as well, the regions of the p-type well 12 and the silicon member 25 where the inversion layer 45 is formed (referring to FIG. 7) is not electromagnetically shielded by other conductive members; portions that are excessively distal to the electrode films 17 are not formed; and therefore, the inversion layer can be formed stably between the source electrode 27 and the silicon pillar 20.

Otherwise, the configuration, the manufacturing method, the operations, and the effects of the embodiment are similar to those of the first embodiment described above.

Although an example is illustrated in the embodiments described above in which the stacked body 15 is formed by alternately stacking the insulating films 16 and the electrode films 17, this is not limited thereto; and the stacked body may be formed by alternately stacking the insulating films 16 and sacrificial films, making the memory hole 41 in the stacked body, forming the silicon member 25, the silicon pillar 20, etc., inside the memory hole 41, making the trench 43 in the stacked body, subsequently removing the sacrificial films via the trench 43, and filling the electrode films.

According to the embodiments described above, a semiconductor memory device having a high ON current and a method for manufacturing the semiconductor memory device can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device, comprising:
a semiconductor substrate;
a stacked body provided on the semiconductor substrate, the stacked body including a plurality of insulating films and a plurality of electrode films, each of the insulating films and each of the electrode films being stacked alternately;
a semiconductor pillar provided inside the stacked body, the semiconductor pillar extending in a stacking direction of the insulating films and the electrode films;
a charge storage film provided between the semiconductor pillar and one of the electrode films;
a tunneling insulating film provided between the semiconductor pillar and the charge storage film;
a blocking oxide provided between the charge storage film and the one of the electrode films; and
a semiconductor member provided between the tunneling insulating film and the semiconductor substrate, between the charge storage film and the semiconductor substrate, and between the blocking insulating film and the semiconductor substrate,
among the plurality of electrode films, one or more electrode films from the bottom being lower selection gate electrodes,
a lower end of the charge storage film being positioned higher than a lower surface of one of the lower selection gate electrodes and positioned lower than an upper surface of the one of the lower selection gate electrodes.

2. The semiconductor memory device according to claim 1, wherein the semiconductor member is interposed between the semiconductor pillar and the semiconductor substrate, and the semiconductor member connects the semiconductor pillar to the semiconductor substrate.

3. The semiconductor memory device according to claim 1, wherein a lower portion of the semiconductor member is disposed lower than an upper surface of the semiconductor substrate, and an upper portion of the semiconductor member is disposed higher than the upper surface of the semiconductor substrate.

4. The semiconductor memory device according to claim 1, wherein the one of the lower selection gate electrodes is the electrode film of the lowermost level.

5. The semiconductor memory device according to claim 1, wherein the one of the lower selection gate electrodes is the electrode film of the second level from the bottom.

6. The semiconductor memory device according to claim 1, wherein a lower end of the tunneling insulating film is positioned the same as or higher than a lower end of the charge storage film.

7. The semiconductor memory device according to claim 1, wherein a lower end of the semiconductor pillar is positioned the same as or higher than a lower end of the tunneling insulating film.

8. The semiconductor memory device according to claim 1, wherein a lower end of the tunneling insulating film becomes higher approaching the semiconductor pillar, and a lower end surface of the lower end of the tunneling insulating film is rounded to be convex.

9. The semiconductor memory device according to claim 1, wherein the lower end of the charge storage film and a lower end of the tunneling insulating film are slanted to become higher approaching the semiconductor pillar.

10. The semiconductor memory device according to claim 9, wherein the lower end of the charge storage film and the lower end of the tunneling insulating film are included in a continuous plane.

11. The semiconductor memory device according to claim 1, wherein a void is made in an interior of the semiconductor member.

12. The semiconductor memory device according to claim 1, wherein the semiconductor pillar contacts the semiconductor substrate.

13. The semiconductor memory device according to claim 1, wherein a lower portion of the charge storage film is bent in a direction toward the semiconductor pillar.

14. The semiconductor memory device according to claim 1, further comprising:
an electrode member provided inside the stacked body, the electrode member extending in the stacking direction, a lower end of the electrode member being connected to the semiconductor substrate; and
an insulating plate provided between the electrode film and the electrode member.

15. The semiconductor memory device according to claim 14, wherein the semiconductor substrate includes:
a first portion contacting the electrode member, a conductivity type of the first portion being an n-type; and
a second portion contacting the semiconductor member, a conductivity type of the second portion being a p-type.

16. A semiconductor memory device, comprising:
a semiconductor substrate;
a stacked body provided on the semiconductor substrate, the stacked body including a plurality of insulating films and a plurality of electrode films, each of the insulating films and each of the electrode films being stacked alternately;
a semiconductor pillar provided inside the stacked body, the semiconductor pillar extending in a stacking direction of the insulating films and the electrode films;
a charge storage film provided between the semiconductor pillar and one of the electrode films;
a tunneling insulating film provided between the semiconductor pillar and the charge storage film;
a blocking oxide provided between the charge storage film and the one of the electrode films; and
a semiconductor member provided between the tunneling insulating film and the semiconductor substrate, between the charge storage film and the semiconductor substrate, and between the blocking insulating film and the semiconductor substrate,
a lower end of the charge storage film being positioned higher than a lower surface of the electrode film of the lowermost level and positioned lower than an upper surface of the electrode film of the lowermost level.

17. A method for manufacturing a semiconductor memory device, comprising:
forming a stacked body on a semiconductor substrate by alternately stacking a plurality of insulating films and a plurality of electrode films;
making a memory hole piercing the stacked body and penetrating an upper portion of the semiconductor substrate;
forming a blocking oxide on an inner surface of the memory hole;
forming a charge storage film on a surface of the blocking insulating film;
forming a tunneling insulating film on a surface of the charge storage film;
forming a semiconductor layer on a surface of the tunneling insulating film;
removing portions of the semiconductor layer, the tunneling insulating film, the charge storage film, and the blocking insulating film disposed on a bottom surface of the memory hole;
making an air gap by removing a lower portion of the semiconductor layer, a lower portion of the tunneling insulating film, and a lower portion of the charge storage film by performing isotropic etching via the memory hole; and
forming a semiconductor member inside the air gap and forming a semiconductor pillar inside the memory hole and on the semiconductor member,
the making of the air gap causing a lower end of the charge storage film to be positioned higher than a lower surface of one of lower selection gate electrodes and positioned lower than an upper surface of the one of the lower selection gate electrodes when one or more electrode films from the bottom of the plurality of electrode films is used as the lower selection gate electrodes, one or more electrode films from the top of the plurality of electrode films is used as upper selection gate electrodes, and the remaining electrode films of the plurality of electrode films are used as word lines.

18. A method for manufacturing the semiconductor memory device according to claim 17, wherein the semiconductor member is formed by epitaxial growth using an exposed surface of the semiconductor substrate as a starting point.

19. The method for manufacturing the semiconductor memory device according to claim 17, wherein the semiconductor member is formed by depositing a semiconductor material via the memory hole.
